(19) United States
(12) Patent Application Publication
(10) Pub. No.: US 2022/0189895 A1
(43) Pub. Date: Jun. 16, 2022

(54) SEMICONDUCTOR DEVICE AND METHOD OF MANUFACTURING SEMICONDUCTOR DEVICE

(71) Applicant: FUJITSU LIMITED, Kawasaki-shi (JP)

(72) Inventor: Masaru Morita, Isehara (JP)

(73) Assignee: FUJITSU LIMITED, Kawasaki-shi (JP)

(21) Appl. No.: 17/401,364

(22) Filed: Aug. 13, 2021

(30) Foreign Application Priority Data
Dec. 15, 2020 (JP) 2020-207479

(51) Int. Cl. H01L 23/00

(52) U.S. Cl. CPC H01L 24/05; H01L 24/16; H01L 24/81; H01L 2224/0401; H01L 2224/05083; H01L 2224/8181; H01L 2224/05118; H01L 2224/05124; H01L 2224/05171; H01L 2224/05169; H01L 2224/16227; H01L 2224/05147

(57) ABSTRACT

A semiconductor device includes a semiconductor substrate configured to include a first electrode layer, and a first barrier layer provided on the first electrode layer and bonded to a metal layer, and a circuit substrate configured to include a second electrode layer, and a second barrier layer provided on the second electrode layer and bonded to the metal layer, wherein the semiconductor substrate including a semiconductor element, and the circuit substrate are bonded via the metal layer containing Sn, a linear expansion coefficient of the first barrier layer is larger than that of the circuit substrate, and a linear expansion coefficient of the second barrier layer is smaller than that of the circuit substrate.

### CROSS-REFERENCE TO RELATED APPLICATION

This application is based upon and claims the benefit of priority of the prior Japanese Patent Application No. 2020-207479 filed on Dec. 15, 2020, the entire contents of which am incorporated herein by reference.

### FIELD

A certain aspect of the embodiments is related to a semiconductor device and a method of manufacturing the semiconductor device.

### BACKGROUND

In a semiconductor device, a metal layer (solder bump) may be used to mount a semiconductor element, and a semiconductor substrate such as a semiconductor package that package the semiconductor element on a circuit substrate. The semiconductor device generates heat as it operates. Here, due to the difference between a linear expansion coefficient (thermal expansion coefficient) of the semiconductor substrate and a linear expansion coefficient of the circuit substrate, a thermal stress acts on the metal layer bonding the semiconductor substrate and the circuit substrate. When the thermal stress repeatedly acts on the metal layer bonding the semiconductor substrate and the circuit substrate, plastic strain is generated in the metal layer and metal fatigue is accumulated. Finally, cracks may occur in the metal layer, and electric conduction in the metal layer may be lost. In order to avoid such a phenomenon, conventionally, it was proposed that the compositions of an electrode pad of the semiconductor substrate (semiconductor chip) and a connection pad of the circuit substrate (wiring substrate) are the same as each other in the solder bump which is the metal layer (see Patent Document 1: Japanese Laid-open Patent Publication No. 2013-48285).

### SUMMARY

According to an aspect of the present disclosure, there is provided a semiconductor device including: a semiconductor substrate configured to include a first electrode laver, and a first barrier layer provided on the first electrode layer and bonded to a metal layer; and a circuit substrate configured to include a second electrode layer, and a second barrier layer provided on the second electrode layer and bonded to the metal layer; wherein the semiconductor substrate including a semiconductor element, and the circuit substrate are bonded via the metal layer containing Sn, a linear expansion coefficient of the first barrier layer is larger than that of the circuit substrate, and a linear expansion coefficient of the second barrier layer is smaller than that of the circuit substrate.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a cross-sectional view of a semiconductor device according to an embodiment;

FIG. 1B is a cross-sectional view illustrating the semiconductor device according to an embodiment in a state where a semiconductor substrate and a circuit substrate are separated from each other;

FIG. 2 is a diagram illustrating a part of the manufacturing process of the semiconductor device according to the embodiment;

FIG. 3 is a diagram illustrating a part of the manufacturing process of the semiconductor device according to the embodiment:

FIG. 4 is a diagram illustrating a part of the manufacturing process of the semiconductor device according to the embodiment;

FIG. 5 is a diagram illustrating a part of the manufacturing process of the semiconductor device according to the embodiment;

FIG. 6 is a cross-sectional view of a semiconductor device according to a comparative example;

FIG. 7A is a perspective view of a simulation model:

FIG. 7B is a plan view of the simulation model;

FIG. 7C is an enlarged side view illustrating the periphery of the solder bump in the simulation model;

FIG. 8A is a plan view illustrating the distribution of the strain which is a simulation result according to the embodiment;

FIG. 8B is a side view illustrating the distribution of the strain which is a simulation result according to the embodiment:

FIG. 9A is a plan view illustrating the distribution of the strain which is a simulation result according to the comparative example:

FIG. 9B is a side view illustrating the distribution of the strain which is a simulation result according to the comparative example; and

FIG. 10 is a cross-sectional view of the semiconductor device according to another embodiment.

### DESCRIPTION OF EMBODIMENTS

However, the Patent Document 1 does not improve the relative misalignment between the electrode pad and the connection pad caused by the difference between the linear expansion coefficient of the semiconductor substrate and the linear expansion coefficient of the circuit substrate when the semiconductor device has more heat, and its effect is considered to be limited.

In one aspect, the present disclosure aims to alleviate the thermal stress acting on the metal layer bonding the semiconductor substrate and the circuit substrate.

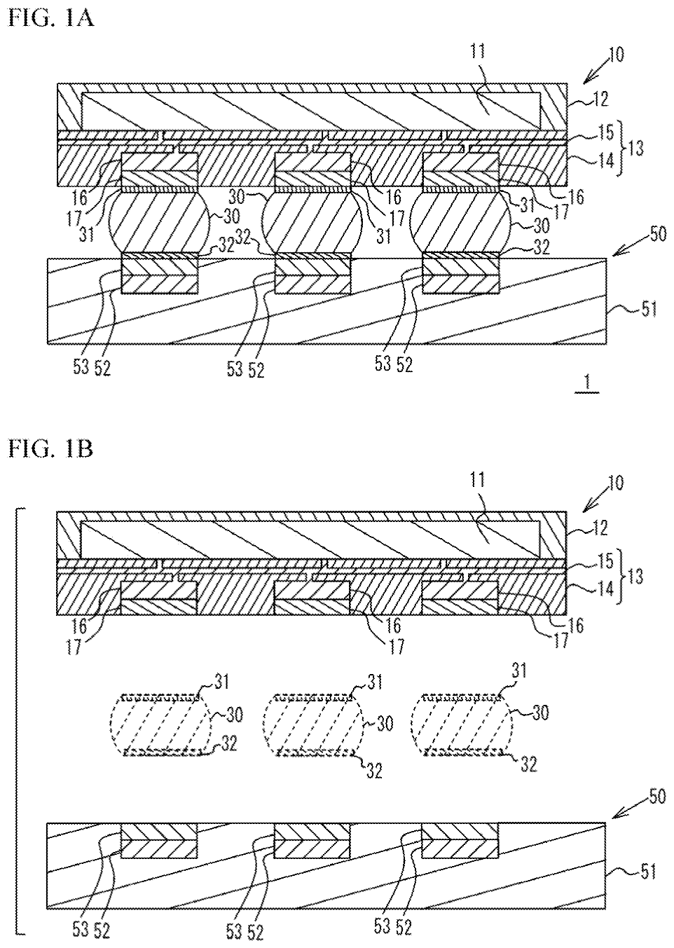

A description will now be given of embodiment of the present invention with reference to attached drawings. It should be noted that a size and a ratio of each element do not correspond to the actual ones in some drawings. Also, some elements which exist in fact may be omitted in some drawings and the sizes of some elements may be illustrated exaggeratingly compared with the actual ones, for convenience of explanation. For example, the dimensions such as the thickness of each layer illustrated in FIG. 1 and the like are different from an actual ratio. Further, the number of solder bumps arranged in an array shape in the drawings also does not indicate an actual number.

### Embodiment

First, a semiconductor device 1 according to the embodiment will be described with reference to FIGS. 1A and 1B. The semiconductor device 1 includes a semiconductor substrate 10 and a circuit substrate 50. FIG. 1A is a cross-sectional view of the semiconductor device 1 according to an embodiment. FIG. 1B illustrates a state in which the semiconductor device 1 is separated into the semiconductor substrate 10 and the circuit substrate 50 in order to make the structure of the semiconductor device 1 easy to understand.

In the semiconductor device 1, the semiconductor substrate 10 and the circuit substrate 50 which are arranged to face each other are bonded via solder bumps 30 corresponding to a metal layer. The semiconductor device 1 in this embodiment is used as a millimeter-wave package used in a communication base or the like. However, this is merely one example. The semiconductor device 1 can be applied to conventionally known various applications such as a CPU (Central Processing Unit) that performs various operations, a memory that temporarily stores information, by connecting semiconductor elements having various functions to each other.

The semiconductor substrate 10 has a semiconductor package structure, and includes a semiconductor element 11 mainly made of silicon (Si) and a scaling resin portion 12 provided around the semiconductor element 11. The semiconductor substrate 10 has a FOWLP (Fanout wafer level package) structure, and a rewiring layer 13 is provided on one surface of the semiconductor element 11. The rewiring layer 13 includes an insulating film layer 14 and a wiring 15. The semiconductor substrate 10 further includes a first electrode layer 16 and a first barrier layer 17 provided in the array shape on a surface facing the circuit substrate 50.

The wiring 15 provided in the rewiring layer 13 is copper (Cu) wiring from the viewpoint of ensuring good electric conductivity. The wiring 15 branches in the insulating film layer 14, connects the semiconductor element 11 and the first electrode layer 16, and secures the electric conduction between the semiconductor element 11 and the first electrode layer 16.

The first electrode layer 16 is a Cu electrode layer as well as the wiring 15. A plurality of first electrode layers 16 are provided in the insulating film layer 14, and the first barrier layer 17 is provided on each of the first electrode layers 16. The total of a surface area of the first barrier layer 17 facing the circuit substrate 50 occupies approximately half of the surface area of the semiconductor substrate 10 facing the circuit substrate 50. The first barrier layer 17 is made of zinc (Zn). The function of the first barrier layer 17 will be described in detail later.

Although the first electrode layer 16 and the first barrier layer 17 in this embodiment am provided to be buried in the insulating film layer 14, they may be provided to be exposed from the upper surface of the insulating film layer 14.

The circuit substrate 50 is a printed wiring substrate having a flame retardant grade of FR4, and includes a second electrode layer 52 and a second barrier layer 53 on a surface of a substrate body 51 facing the semiconductor substrate 10. The substrate body 51 is formed by impregnating a glass cloth with an epoxy resin. The circuit substrate 50 includes a Cu wiring provided in the substrate body 51, but the Cu wiring is omitted in each drawing. The second electrode layer 52 is a Cu electrode layer provided at the end of the Cu wiring. A plurality of second electrode layers 52 are provided in correspondence with the plurality of first electrode layers 16, and the second barrier layer 53 is provided on each of the second electrode layers 52. The second barrier layer 53 is made of chromium (Cr). The function of the second barrier layer 53 will be described in detail later.

Although the second electrode layer 52 and the second barrier layer 53 of the present embodiment are provided to be buried in the substrate body 51, they may be provided to be exposed from the upper surface of the substrate body 51.

The solder bump 30 is made of a solder material containing tin (Sn) as a main component, specifically Sn-3.0Ag-0.5Cu solder.

The first barrier layer 17 is Zn and the second barrier layer 53 is Cr. These materials are selected as metallic materials that react with Sn-3.0Ag-0.5Cu solder forming the solder bump 30. Thereby, a first intermetallic compound layer (Intermetallic Layer; hereinafier referred to as “first IMC layer”) 31 containing components of Zn and Sn-3.0Ag-0.5Cu solder is formed between the first barrier layer 17 and the solder bump 30. Further, a second intermetallic compound layer (hereinafter referred to as “second IMC layer”) 32 containing components of Cr and Sn-3.0Ag-0.5Cu solder is formed between the second barrier layer 53 and the solder bump 30. The first IMC layer 31 is made of Zn₉Sn₉₁. The second IMC layer 32 is made of Cr₂Sn.

Hereinafter, the dimension and the shape of each part of the semiconductor device 1 will be described. However, the dimension and the shape indicated below am examples, and are not limited thereto. The surface of the semiconductor substrate 10 having the package structure, which faces the circuit substrate 50, is a squaw of 6.5 mm×6.5 mm, and its thickness is 0.6 mm. The semiconductor element 11 included in the semiconductor substrate 10 is a square of 6.0 mm×6.0 mm. The first electrode layers 16 having a diameter of 300 μm and a thickness of 10 pun are arranged in an array shape on the surface of the semiconductor substrate 10 facing the circuit substrate 50. The first barrier layer 17 having a diameter of 300 μm and a thickness of 10 μm is provided on each of the first electrode layers 16. The surface of the circuit substrate 50 facing the semiconductor substrate 10 is a square of 10.0 mm 10.0 mm, and its thickness is 1 mm. The second electrode layers 52 having a diameter of 300 μm and a thickness of 10 μm are arranged in an array shape on the surface of the circuit substrate 50 facing the semiconductor substrate 10. The second barrier layer 53 having a diameter of 300 μm and a thickness of 10 μm is provided on each of the second electrode layers 52. Each of the solder bumps 30 has a diameter of 400 μm.

Next, the first barrier layer 17 and the second barrier layer 53 will be described in detail. A melting point of Sn, which is a main component of Sn-3.0Ag-0.5Cu solder forming the solder bump 30, is about 220° C. If the first electrode layer 16 and the second electrode layer 52 are directly bonded to the solder bump 30, Cu forming the first electrode layer 16 and the second electrode layer 52 reacts quickly with the solder bump 30, and a Cu—Sn compound layer such as Cu₃Sn and Cu₆Sn₅ appears. As a result, the regions of the Cu electrodes are reduced. The first barrier layer 17 and the second barrier layer 53 can slow down a rate of thermal diffusion more than Cu, and suppress a decrease in the regions of the Cu electrodes. In addition, the first barrier layer 17 and the second barrier layer 53 are provided and the first IMC layer 31 and the second IMC layer 32 are formed, so that strong bonding between the solder bump 30, and the first electrode layer 16 and the second electrode layer 52 can be achieved. Although the thicknesses of the first barrier layer 17 and the second barrier layer 53 are not limited, it is desirable to make each thickness 1-5 μm in order to increase a barrier effect.

Next, the linear expansion coefficient of the first barrier layer 17 will be described. The first barrier layer 17 is made of Zn. The linear expansion coefficient of Zn is 33.0 ppm. In contrast, the linear expansion coefficient of the circuit substrate 50 is approximately 16 ppm. That is, the linear expansion coefficient of the first barrier layer 17 is more than that of the circuit substrate 50. The second electrode layer 52 is a Cu electrode layer, and the linear expansion coefficient thereof is 17.7 ppm. The linear expansion coefficient of the first barrier layer 17 is more than that of the second electrode layer 52.

On the other hand, the second barrier layer 53 is made of Cr. The linear expansion coefficient of Cr is 6.2 ppm. That is, the linear expansion coefficient of the second barrier layer 53 is smaller than the linear expansion coefficient of the circuit substrate 50, and is also smaller than the linear expansion coefficient of the second electrode layer 52. Conventionally, nickel (Ni) may be used as a material to form the barrier layer, but the linear expansion coefficient of Ni is 13.3 ppm, and the linear expansion coefficient of the second barrier layer 53 is smaller than the linear expansion coefficient of Ni.

Here, the main component of the semiconductor element 11 included in the semiconductor substrate 10 is Si, and the linear expansion coefficient of the semiconductor substrate 10 (i.e., the semiconductor element 11) is 3.9 ppm. On the other hand, the linear expansion coefficient of the circuit substrate 50 is approximately 16 ppm as described above, and there is a difference of 12 ppm or more between the circuit substrate 50 and the semiconductor substrate 10. In the semiconductor device 1, the semiconductor substrate 10 (semiconductor element 11) and the circuit substrate 50, which have such different linear expansion coefficients, are bonded together via the solder bump 30.

Since the semiconductor device 1 generates heat when it is operated, it is repeatedly heated and cooled according to an operating state. As a result, thermal stress repeatedly acts on the solder bump 30 that bonds the semiconductor substrate 10 and the circuit substrate 50 having the different linear expansion coefficients. Such repeated thermal stresses also act on the solder bump 30 when a thermal cycle test which is a reliability test of the semiconductor device 1 is conducted. In the thermal cycle test, for example, the heating and cooling of the semiconductor device 1 is repeated between −40° C. and 125° C.

If the first barrier layer 17 and the second barrier layer 53 are not provided. 10 or if the first barrier layer 17 and the second barrier layer 53 are provided and the material such as Ni is selected, it is assumed that a deviation in the position and the dimension between the first electrode layer 16 and the second electrode layer 52 will be large. As a result, the thermal stress acting on the solder bump 30 increases, and if this stress repeatedly acts on the solder bump 30, the crack may occur in the solder bump 30. In particular, the crack often occurs in a part of the solder bump 30 near the semiconductor substrate 10, where the solder bump 30 is greatly deformed and the thermal stress is easily concentrated.

In the present embodiment, the first barrier layer 17 made of Zn and the second barrier layer 53 made of Cr are provided, so that a difference between the apparent linear expansion coefficient of the semiconductor substrate 10 and the apparent linear expansion coefficient of the circuit substrate 50 is reduced.

In other words, first, the linear expansion coefficient of the first barrier layer 17 provided on the semiconductor substrate 10 is increased, so that differences in a thermal expansion amount and a thermal contraction amount between bonding targets (i.e., the semiconductor substrate 10 and the circuit substrate 50) of the solder bump 30 are reduced. The circuit substrate 50 has a larger linear expansion coefficient than the semiconductor substrate 10, and the thermal expansion amount and the thermal contraction amount of the circuit substrate 50 are also larger than those of the semiconductor substrate 10. Therefore, the linear expansion coefficient of the first barrier layer 17 is increased, and the thermal expansion amount and the thermal contraction amount of each of the first barrier layers 17 are increased. This reduces the differences in the thermal expansion amount and the thermal contraction amount between the bonding targets (i.e., the semiconductor substrate 10 and the circuit substrate 50) of the solder bump 30, and reduces the thermal stress in each solder bump 30.

A total thermal expansion amount and A total thermal contraction amount in an object increase as the size of the object increases. Therefore, the linear expansion coefficient of the first barrier layer 17 having a smaller dimension is made larger than that of the circuit substrate 50, so that the differences in the thermal expansion amount and the thermal contraction amount between the bonding targets of the solder bump 30 are reduced more effectively. Focusing on the first barrier layer 17 and the second electrode layer 52, even if the linear expansion coefficient of the first barrier layer 17 is made larger than that of the second electrode layer 52, the differences in the thermal expansion amount and the thermal contraction amount between them can be reduced.

In addition, the linear expansion coefficient of the second barrier layer 53 provided on the circuit substrate 50 is reduced, so that the differences in the thermal expansion amount and the thermal contraction amount between the bonding targets of the solder bump 30 is more reduced. By reducing the linear expansion coefficient of the second barrier layer 53, which is provided on the circuit substrate 50 and is actually bonded to the solder bump 30, the thermal expansion amount and the thermal contraction amount of each second barrier layer 53 is reduced. This reduces the differences in the thermal expansion amount and the thermal contraction amount between the bonding targets of the solder bump 30, and reduces the thermal stress in each solder bump 30. By making the linear expansion coefficient of the second barrier layer 53 smaller than that of Ni, which is sometimes conventionally employed as a material for the barrier layer, the differences in the thermal expansion amount and the thermal contraction amount between the bonding targets of the solder bump 30 can be effectively reduced.

Thus, in the semiconductor device 1 of this embodiment, the thermal stress in the solder bump 30 is reduced and the occurrence of the crack is suppressed. As a 30 result, the bonding reliability of the semiconductor device 1 is improved.

Focusing on the linear expansion coefficients of the first electrode layer 16 and the first barrier layer 17, there is a difference of nearly 16 ppm between them. However, since the first electrode layer 16 and the first barrier layer 17 have small individual areas and are firmly bonded to each other, the occurrence of the problem due to the thermal stress at a boundary between them is suppressed. Similarly, there is a difference in the linear expansion coefficient between the second electrode layer 52 and the second barrier layer 53. However, since the second electrode layer 52 and the second barrier layer 53 have small individual areas and are firmly bonded to each other, the occurrence of the problem due to the thermal stress at a boundary between them is suppressed.

Also, there is a difference in the linear expansion coefficient between the first barrier layer 17 and the second barrier layer 53 which are actually bonded by the solder bump 30. However, since the first barrier layer 17 and the second barrier layer 53 have small individual areas, the occurrence of the problem due to the thermal stress is suppressed.

### (Manufacturing Method)

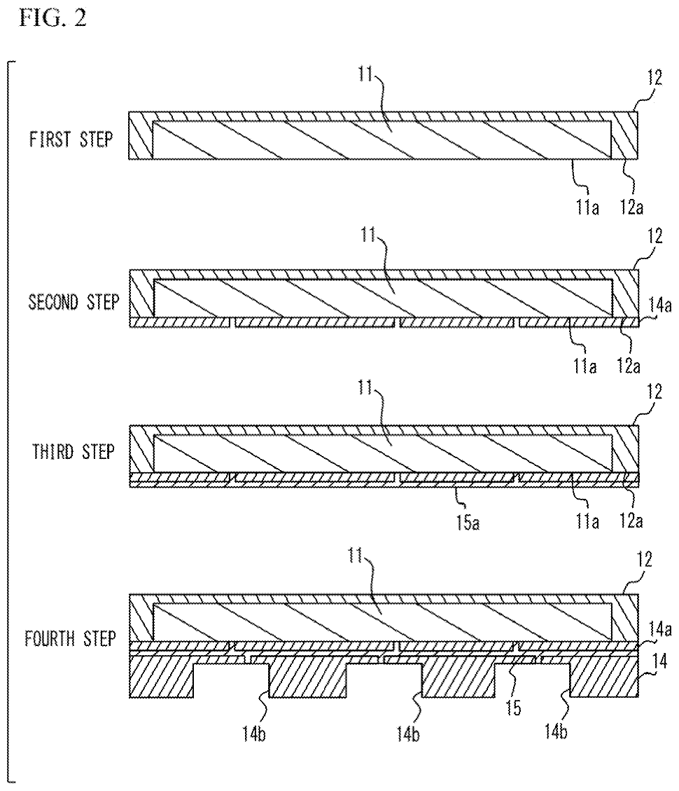

Next, an example of a manufacturing method of the semiconductor device 1 according to the embodiment will be described with reference to FIGS. 2 to 5. First, in a first step illustrated in FIG. 2, the semiconductor element 11 provided with a circuit forming surface 11a is prepared, and the sealing resin portion 12 is provided so as to cover the periphery of the semiconductor element 1I by using a molding device. At this time, the circuit forming surface 1a (i.e., a lower surface in FIG. 2) of the semiconductor element 11 is kept in an open state.

Next, in a second step illustrated in FIG. 2, a portion 14a of the insulating film layer 14 (see FIG. 1A) is formed so as to cover the circuit forming surface 1a of the semiconductor element 11 and a continuous surface 12a of the sealing resin portion 12 that is flush with this circuit forming surface 11a. Then, using an exposure apparatus, patterning is performed on the insulating film layer 14 in accordance with the wiring 15 (see FIG. 1A).

Then, in a third step illustrated in FIG. 2, a part 15a of the wiring 15 is formed by electrolytic Cu plating. After that, by repeating the formation of the insulating film layer and the patterning and the electrolytic Cu plating, the insulating film layer 14 and the wiring 15 having a desired pattern are obtained as in a fourth step illustrated in FIG. 2. At this time, the insulating film layer 14 is provided with a plurality of recesses 14b in which the first electrode layer 16 and the first barrier layer 17 are provided. The wiring 15 may be formed by electroless Cu plating.

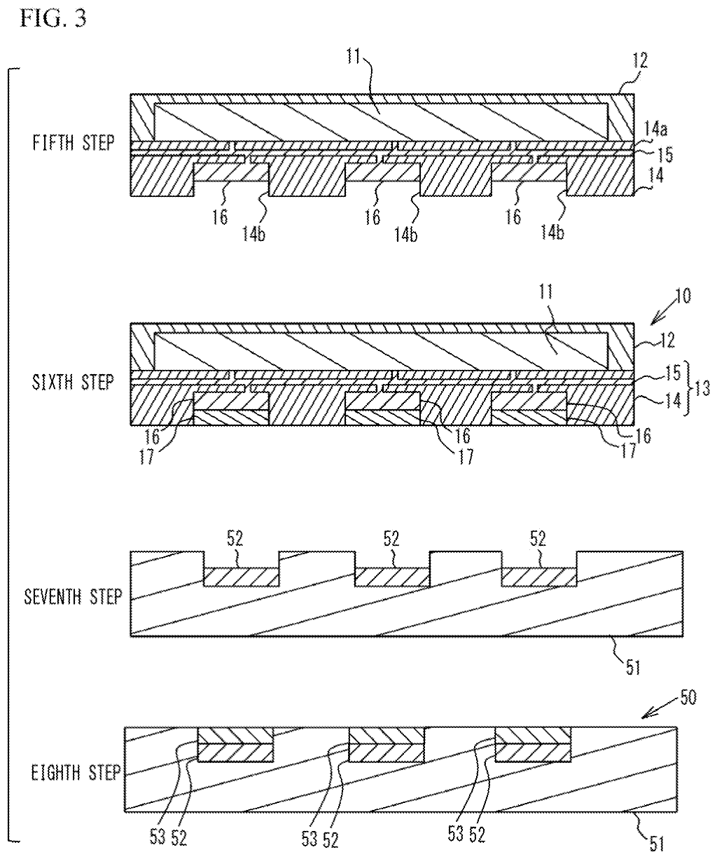

Next, in a fifth step illustrated in FIG. 3, electrolytic Cu plating is applied to the recess 14b to form the first electrode layer 16. Then, the first barrier layer 17 is formed on the first electrode layer 16 as in a sixth step illustrated in FIG. 3. The first barrier layer 17 is formed by electroless Zn plating. Thereby, the semiconductor substrate 10 is obtained. Since Zn is easily oxidized, the first barrier layer 17 is formed with Zn, and then a gold (Au) layer, for example, may be provided on the first barrier layer 17 to suppress the oxidation of the first barrier layer 17. The Au layer diffuses throughout and disappears as a layer in the subsequent step of forming the solder bump 30. The Au layer may be provided in the same way after the second barrier layer 53 is formed as described later. The Au layer can be provided in the same way even when other materials are used as the first and second barrier layers.

The circuit substrate 50 is obtained by providing the second electrode layer 52 on the substrate body SI as in a seventh step illustrated in FIG. 3, and by forming the second barrier layer 53 on the second electrode layer 52 as in an eighth step illustrated in FIG. 3. The steps related to the circuit substrate 50 up to the formation of the second electrode layer 52 on the substrate body 51 illustrated in the seventh step includes a step of forming the wiring and the second electrode layer 52 on the glass core forming the substrate body 51 by repeating patterning of the insulating film layer, electrolytic Cu plating, or electroless Cu plating. Since these steps are conventionally known steps, detailed description thereof will be omitted here. The formation of the second barrier layer 53 illustrated in the eighth step is performed by electrolytic Cr plating.

The first to sixth steps for obtaining the semiconductor substrate 10 and the seventh and the eighth steps for obtaining the circuit substrate 50 may be carried out in parallel. In other words, it is sufficient if the semiconductor substrate 10 and the circuit substrate 50 can be obtained at the same time.

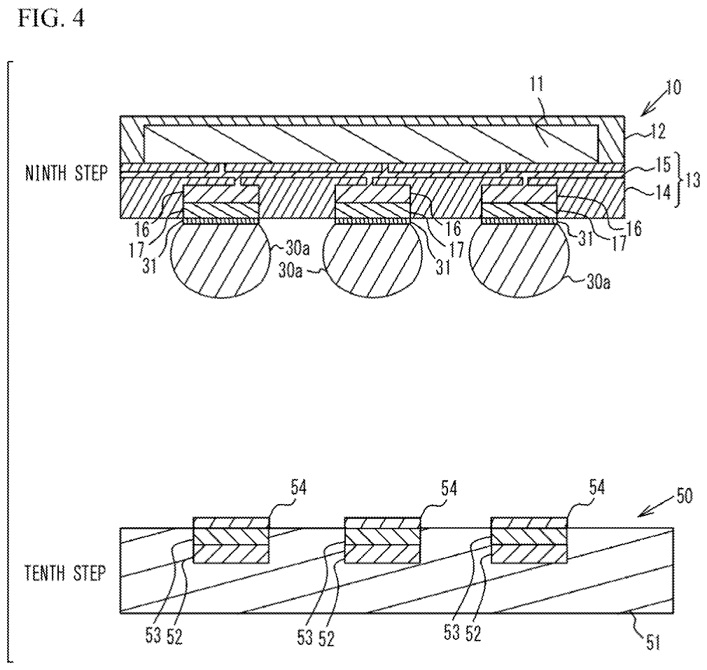

After obtaining the semiconductor substrate 10 illustrated in the sixth step, the solder ball 30a for forming the solder bump 30 (see FIG. 1A) is placed on the first barrier layer 17 as in a ninth step illustrated in FIG. 4 and heated by the reflow device. Thereby, the first barrier layer 17 and the solder ball 30a are bonded together to form the solder bump 30. At this time, the first IMC layer 31 is formed at a boundary between the first barrier layer 17 and the solder bumps 30. Since the solder bump 30 (i.e., solder ball 30a) in this embodiment uses Sn-3.0Ag-0.5Cu solder, a reflow temperature is set to 230 to 260° C. The reflow temperature is appropriately set according to the solder material to be used.

After the solder ball 30a is bonded to the first barrier layer 17, a solder paste 54 is printed on the second electrode layer 52 included in the circuit substrate 50 as in a tenth step illustrated in FIG. 4, using a metal mask.

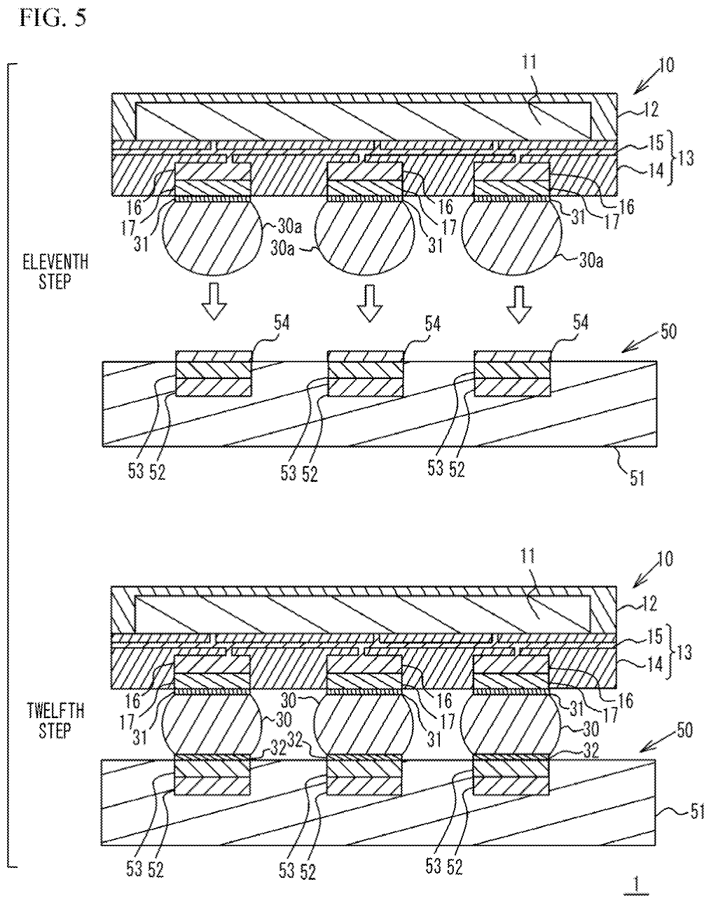

In an eleventh step illustrated in FIG. 5, the position of the solder bump 30 (the solder ball 30a) bonded on the semiconductor substrate 10 and the position of the second electrode layer 52 (the second barrier layer 53) on the circuit substrate 50 are aligned using a flip chip device. Then, while the semiconductor substrate 10 is pressed toward the circuit substrate 50, the semiconductor substrate 10 is temporarily fixed to the circuit substrate 50 by heating to about 230 to 250° C. Then, in a twelfth step, the semiconductor substrate 10 and the circuit substrate 50 are heated by the reflow device, the solder bump 30 is also bonded to the second barrier layer of the circuit substrate 50, and the bonding by the solder bump 30 is completed. At this time, the second IMC layer 32 is formed at a boundary between the second barrier layer 53 and the solder bump 30.

Finally, the semiconductor substrate 10 and the circuit substrate 50 which are bonded to each other are cleaned with organic solvents, etc., so that the semiconductor device 1 is obtained.

### (Simulation)

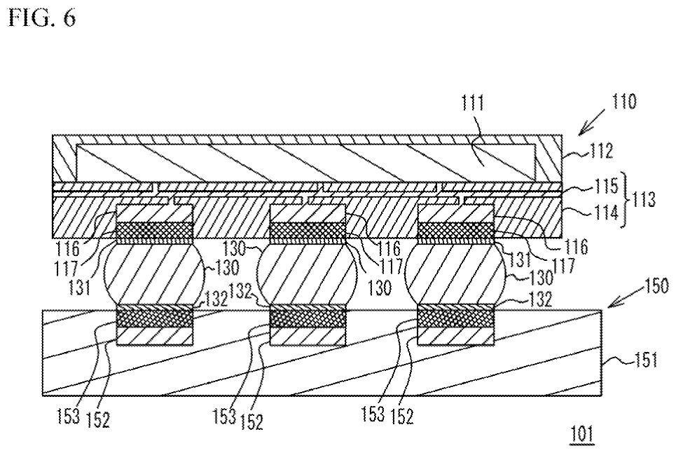

Next, the simulation for confirming the effect of the semiconductor device 1 of the present embodiment will be described. The simulation was performed on the semiconductor device 1 of the embodiment and also on a semiconductor device 101 of a comparative example illustrated in FIG. 6.

In the semiconductor device 101 of the comparative example, a semiconductor substrate 110 and a circuit substrate 150 are bonded via solder bumps 130, as in the semiconductor device 1 of the embodiment.

The semiconductor substrate 110 in the comparative example includes a semiconductor element 111, a scaling resin portion 112, a rewiring layer 113, an insulating film layer 114, a wiring 115, and a first electrode 116. These are common to the semiconductor substrate 10 of the embodiment. The semiconductor substrate 110 includes a first barrier layer 117. However, the first barrier layer 117 is made of Ni, which is different from the semiconductor substrate 10 of the embodiment.

The circuit substrate 150 in the comparative example includes a substrate body 151 and a second electrode layer 152. These are common to the circuit substrate 50 of the embodiment. The circuit substrate 150 includes a second barrier layer 153. The second barrier layer 153 is made of Ni. and both of a first IMC layer 131 and a second IMC layer 132 are made of Ni₃Sn. This is different from the circuit substrate 50 of the embodiment.

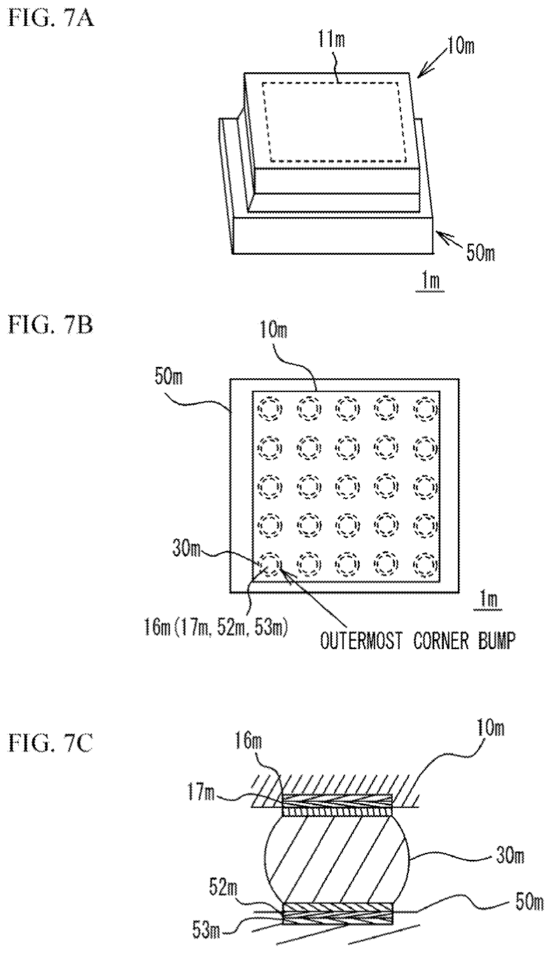

The simulation was conducted using simulation models illustrated in FIGS. 7A to 7C. A semiconductor device 1m in the simulation model includes a semiconductor substrate 10m and a circuit substrate 50m. The semiconductor substrate 10m includes a semiconductor element 11m, a first electrode layer 16m, and a first barrier layer 17m. The circuit substrate 50m includes a second electrode layer 52m and a second barrier layer 53m. The first barrier layer 17m and the second barrier layer 53m are bonded by a solder bump 30m.

The simulation model is a quarter model in which the length of each side of the semiconductor device 1 in FIG. 1 is halved. Therefore, the semiconductor substrate 10m is a square of 3.25 mm×3.25 mm, and the semiconductor element 11m is a square of 3.0 mm×3.0 mm. The circuit substrate 50m is a square of 5.0 mm×5.0 mm. However, the thickness of the semiconductor substrate 10m is 0.6 mm, the diameters and the thicknesses of the first electrode layer 16m and the first barrier layer 17m are 300 μm and 10 μm, respectively and these have the same dimensions as the actual semiconductor substrate 10. The thickness of the circuit substrate 50m is 1.0 mm, the diameters and the thicknesses of the second electrode layer 52m and the second barrier layer 53m are 300 μm and 10 μm, respectively, and these have the same dimensions as the actual circuit substrate 50.

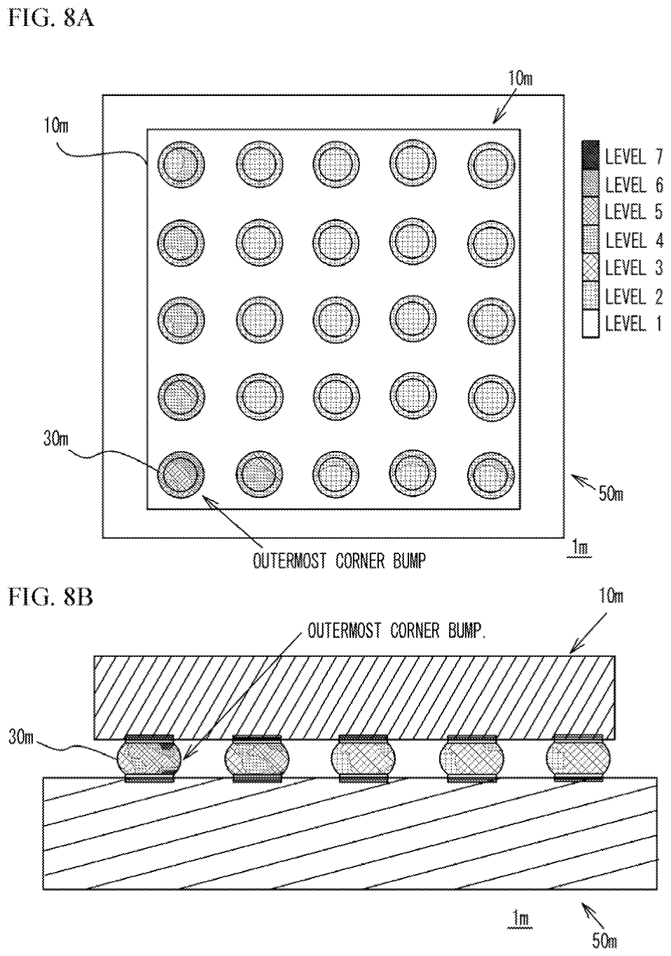

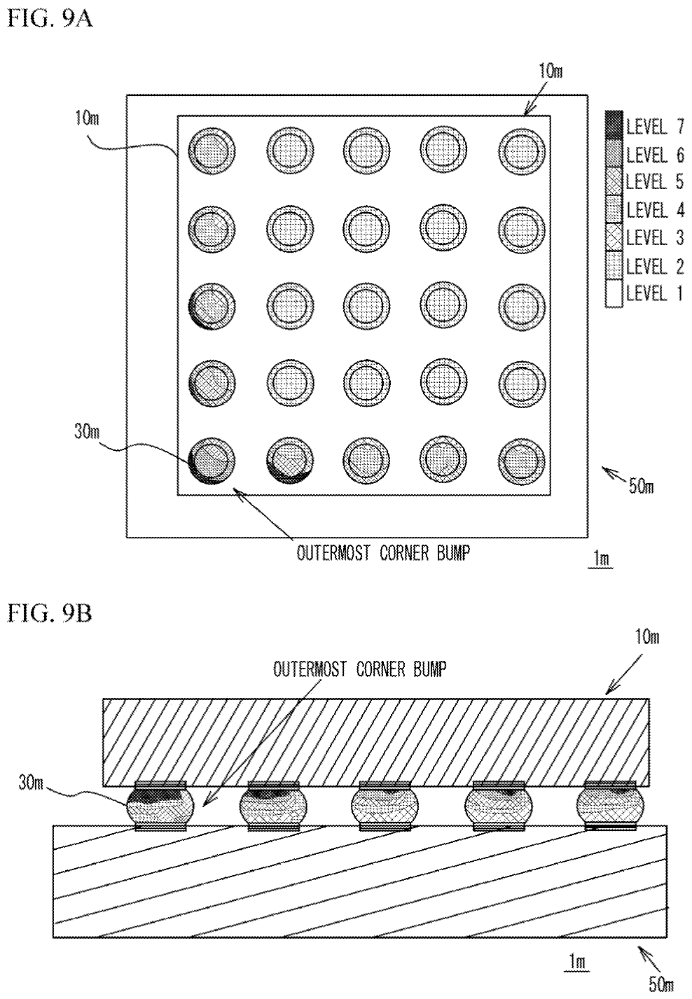

The simulation was conducted by setting the linear expansion coefficients of each part in the simulation model, and by applying, to the simulation model, one cycle of increasing the temperature from −40° C. to 125° C. and then decreasing it to −40° C. again, as the thermal cycle test which is the bonding reliability test. FIGS. 8A and 8B illustrate simulation results in which the linear expansion coefficient of each part of the semiconductor device 1 of the embodiment is set. FIGS. 9A and 9B illustrate simulation results in which the linear expansion coefficient of each part of the semiconductor device 101 of the comparative example is set. The simulation result in each drawing indicates the magnitude of the strain in each part stepwise from a level 1 to a level 7 with different shaded patterns. The level of strain increases from the level 1 toward the level 7.

In both the simulation results of the embodiment and the comparative example, it can be seen that a solder bonding portion at the outermost corner of the semiconductor device 1m is a portion where a cumulative inelastic (plastic) strain amount is most accumulated and is the most easily broken.

In the simulation result of the embodiment, it can be seen that in the outermost corner bump, the cumulative inelastic strain amount equivalent to the level 7 (about 0.031) is slightly generated at a position close to the semiconductor substrate 10m and a position close to the circuit substrate 50m. Further, it can be seen that the cumulative inelastic strain amount corresponding to a level 4 (about 0.025) or less is obtained in the outermost bumps other than the corner bump. As described above, in the embodiment, it can be seen that the outermost bumps other than the corner bump have a significantly smaller amount of strain than the corner bump.

On the other hand, in the simulation result of the comparative example, the cumulative inelastic strain amount equivalent to the level 7 (0.035 or more) is obtained in a wider range than that of the embodiment in the outermost corner bump. Further, referring to FIG. 9B, it can be seen that the cumulative inelastic strain amount having a high level is observed more at the position close to the semiconductor substrate 10m, and the cumulative inelastic strain amount at the position close to the circuit substrate 50m has a low level (0.025 or less). Therefore, in the comparative example, it is considered that there is a high possibility that the solder bump 30m is broken at the position close to the semiconductor substrate 10m. Further, the cumulative inelastic strain amount of the level 7 (0.031 or more) is also observed in the outermost bumps adjacent to the corner bump.

Thus, comparing the simulation result of the embodiment with that of the comparative example, it was found that the semiconductor device 1 of the embodiment disperses the thermal stress and prevents the thermal stress from concentrating at specific locations, compared with the semiconductor device 101 of the comparative example.

In addition, the thermal cycle test was conducted by repeating the cycle in which the temperature of the semiconductor device 1m was increased from 40° C. to 125° C. and then decreased to −40° C. again. As a result, in the simulation result of the embodiment, disconnection was observed in the outermost corner bump for the first time at 1250 cycles. In contrast, in the simulation result of the comparative case, the similar disconnection was observed at 920 cycles. Thereby, it was confirmed that the bonding reliability was improved in the semiconductor device 1 of the embodiment.

Thus, according to the semiconductor device 1 of this embodiment, the thermal stress acting on the solder bump 30 (metal layer) that bonds the semiconductor substrate 10 and the circuit substrate 50 can be alleviated.

### Other Embodiment

In the semiconductor device 1 of the embodiment, Zn is used as the material of the first barrier layer 17, and Cr is used as the material of the second barrier layer 53. Although Zn is selected from the viewpoint of making the linear expansion coefficient of the first barrier layer 17 made larger than that of the circuit substrate 50, the first barrier layer may be formed by other materials that satisfy this condition. Although Cr is selected from the viewpoint of making the linear expansion coefficient of the second barrier layer 53 smaller than that of the circuit substrate 50, the second barrier layer may be formed by other materials that satisfy this condition.

For example, the first barrier layer may be made of aluminum (Al) and the second barrier layer may be made of platinum (Pt). The linear expansion coefficient of Al is 23.8 ppm, which is larger than the linear expansion coefficient of the circuit substrate 50. The linear expansion coefficient of Pt is 8.8 ppm, which is smaller than the linear expansion coefficient of the circuit substrate 50.

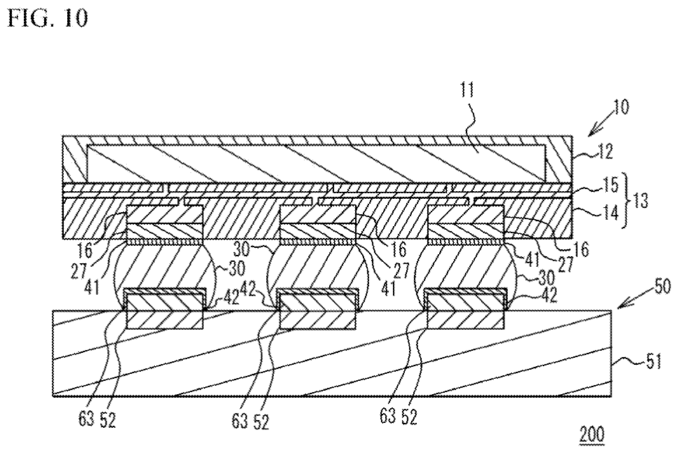

A semiconductor device 200 illustrated in FIG. 10 include a first barrier layer 27 in place of the first barrier layer 17 included in the semiconductor device 1 of the embodiment, and a second barrier layer 63 in place of the second barrier layer 53. The first barrier layer 27 is made of Al. The second barrier layer 63 is made of Pt. Further, as the material of the barrier layer is changed in this way, a first IMC layer 41 includes Ag₂Al, Cu₃Al₂, and Cu₉Al₄. Further, a second IMC layer 42 includes PtSn₄. The second barrier layer 63 is provided so that side surfaces thereof are also exposed from the circuit substrate 50. Therefore, the second IMC layer 42 is formed up to a position where it covers the side surfaces of the second barrier layer 63.

Since the other configurations of the semiconductor device 200 illustrated in FIG. 10 are common to those of the semiconductor device 1 of the embodiment, the same components are described with the same reference numbers in FIG. 10, but the dimension of each part is different as follows. That is, the surface of the semiconductor substrate 10 facing the circuit substrate 50 is a square of 10.0 mm-10.0 mm, and its thickness is 0.6 mm. The semiconductor element 11 included in the semiconductor substrate 10 is a square of 8.0 mm-8.0 mm. The first electrode layers 16 having a diameter of 280 pin and a thickness of 10 μm are arranged in the array shape on the surface of the semiconductor substrate 10 facing the circuit substrate 50. The first barrier layer 27 having a diameter of 280 μm and a thickness of 10 μm is provided on each first electrode layer 16. The surface of the circuit substrate 50 facing the semiconductor substrate 10 is a square of 15.0 mm×15.0 mm, and its thickness is 1.0 mm. The second electrode layers 52 having a diameter of 280 μm and a thickness of 10 μm are arranged in the array shape on the surface of the circuit substrate 50 facing the semiconductor substrate 10. The second barrier layer 63 having a diameter of 280 μm and a thickness of 10 μm is provided on each second electrode layer 52.

The semiconductor device 200 can be manufactured in the same manner as the semiconductor device 1 of the embodiment, but the first barrier layer 27 is provided by sputtering Al. The second barrier layer 63 is provided by sputtering Pt.

When the simulation of the thermal cycle test between −40° C. and 125° C. was performed on such a semiconductor device 200 in the same manner as in the semiconductor device 1 of the embodiment, the disconnection was observed in the outermost corner bump for the first time at 1030 cycles. On the other hand, in the simulation performed by matching the dimensions for the same structure as the comparative example illustrated in FIG. 6, the disconnection was observed in the outermost corner bump at 810 cycles. Thus, it was confirmed that the bonding reliability of the semiconductor device 200 was improved.

Both of the semiconductor substrate 10 included in the semiconductor device 1 and the semiconductor device 200 described above have the package structure. However, the package structure is not essential, and the first electrode may be provided on the semiconductor element, and the first barrier layer having a predetermined linear expansion coefficient may be formed on the first electrode.

In the above example, the first barrier layer was made of Zn and Al. and the second barrier layer was made of Cr and Pt. However, the barrier layer may be made of metals having these as main components, which can maintain the predetermined relationship of the linear expansion coefficient.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A semiconductor device comprising:
a semiconductor substrate configured to include a first electrode layer, and a first barrier layer provided on the first electrode layer and bonded to a metal layer; and
a circuit substrate configured to include a second electrode layer, and a second barrier layer provided on the second electrode layer and bonded to the metal layer;
wherein the semiconductor substrate including a semiconductor element, and the circuit substrate are bonded via the metal layer containing Sn,
a linear expansion coefficient of the first barrier layer is larger than that of the circuit substrate, and
a linear expansion coefficient of the second barrier layer is smaller than that of the circuit substrate.

2. The semiconductor device as claimed in claim 1, wherein
the linear expansion coefficient of the first barrier layer is larger than that of the second electrode layer.

3. The semiconductor device as claimed in claim 1, wherein
the linear expansion coefficient of the second barrier layer is smaller than that of Ni.

4. The semiconductor device as claimed in claim 1, wherein
the first electrode layer and the second electrode layer are copper electrode layers.

5. The semiconductor device as claimed in claim 1, wherein
the first barrier layer is formed of a metal material that reacts with the metal layer, and
the semiconductor device includes a first intermetallic compound layer between the first barrier layer and the metal layer, the first intermetallic compound layer containing a component of a metal material forming the first barrier layer and a component of the metal layer.

6. The semiconductor device as claimed in claim 1, wherein
the second barrier layer is formed of a metal material that reacts with the metal layer, and
the semiconductor device includes a second intermetallic compound layer between the second barrier layer and the metal layer, the second intermetallic compound layer containing a component of a metal material forming the second barrier layer and a component of the metal layer.

7. The semiconductor device as claimed in claim 1, wherein
a metal material forming the first barrier layer contains at least one of Zn and Al.

8. The semiconductor device as claimed in claim 1, wherein
a metal material forming the second barrier layer contains at least one of Cr and Pt.

9. A method of manufacturing a semiconductor device in which a semiconductor substrate including a semiconductor element, and a circuit substrate are bonded via a metal layer containing Sn, the method comprising:
forming a first electrode layer on the semiconductor substrate;
forming a first barrier layer on the first electrode layer, the first electrode layer having a linear expansion coefficient larger than that of the circuit substrate;
forming a second electrode layer on the circuit substrate;
forming a second barrier layer on the second electrode layer, the second barrier layer having a linear expansion coefficient smaller than that of the circuit substrate; and
bonding the first barrier layer and the second barrier layer via the metal layer.

10. The method of manufacturing the semiconductor device as claimed in claim 9, wherein
the linear expansion coefficient of the first barrier layer is larger than that of the second electrode layer.

11. The method of manufacturing the semiconductor device as claimed in claim 9, wherein
the linear expansion coefficient of the second barrier layer is smaller than that of Ni.

12. The method of manufacturing the semiconductor device as claimed in claim 9, wherein
the first electrode layer and the second electrode layer are copper electrode layers.

13. The method of manufacturing the semiconductor device as claimed in claim 9, wherein
the first barrier layer is formed of a metal material that reacts with the metal layer, and
the semiconductor device includes a first intermetallic compound layer between the first barrier layer and the metal layer, the first intermetallic compound layer containing a component of a metal material forming the first barrier layer and a component of the metal layer.

14. The method of manufacturing the semiconductor device as claimed in claim 9, wherein
the second barrier layer is formed of a metal material that reacts with the metal layer, and
the semiconductor device includes a second intermetallic compound layer between the second barrier layer and the metal layer, the second intermetallic compound layer containing a component of a metal material forming the second barrier layer and a component of the metal layer.

15. The method of manufacturing the semiconductor device as claimed in claim 9, wherein
a metal material forming the first barrier layer contains at least one of Zn and Al.

16. The method of manufacturing the semiconductor device as claimed in claim 9, wherein
a metal material forming the second barrier layer contains at least one of Cr and Pt.
